(19) United States
(12) Patent Application Publication
(10) Pub. No.: US 2011/0164160 A1
(43) Pub. Date: Jul. 7, 2011

(54) IMAGE PICKUP DEVICE

(75) Inventor: Yasunari Harada, Ebina-shi (JP)

(73) Assignee: OLYMPUS CORPORATION, Tokyo (JP)

(21) Appl. No.: 12/996,525

(22) PCT Filed: Jun. 5, 2009
(86) PCT No.: PCT/JP2009/060358

§ 371 Date: Dec. 6, 2010

(30) Foreign Application Priority Data
Jun. 9, 2008 (JP) 2008-150317

(51) Int. Cl. H04N 3/14; H04N 5/335

(52) U.S. Cl. 348/302; 348/E05.091; 348/E03.016

(57) ABSTRACT

An A/D conversion unit (11) counts and digitizes a clock having a frequency based on a magnitude of an output signal from a pixel (10a) to generate a count value, calculates a difference between a first count value corresponding to the output signal during a rest period of the pixel (10a) and a second count value corresponding to the output signal of an exposure period of the pixel (10a), and outputs the difference as an image pickup signal of the pixel (10a). A controller (12) makes the A/D converter perform a counting in the output signals during the reset period and during the exposure period of the pixel (10a) in each of a plurality of roughly equal successive small periods, sum up the count values in the small periods whose differences in count value from other small periods are within the prescribed fluctuation width among the count values in every small period to generate the first and second count values, respectively.

### TECHNICAL FIELD

The present invention relates to an image pickup device.

Priority is claimed on Japanese Patent Application No. 2008-150317, filed Jun. 9, 2008, the content of which is incorporated herein by reference.

### BACKGROUND ART

Recently, an image pickup element and a method of controlling the image pickup element are known. The image pickup element includes a light receiving element array and a plurality of A/D conversion circuits. The image pickup element is composed into one IC chip. In the light receiving element array, pixels each of which includes a photoelectric conversion element are disposed in two-dimensional array. The A/D conversion circuit performs an A/D conversion of a reception signal from the light receiving element array.

Also, a method in which the image pickup element performs an A/D conversion of a signal only in a required two-dimensional area is known. Also, a method of increasing a resolution of an A/D conversion without changing a voltage range where an A/D conversion can be performed is known. By this method, a sophisticated process such as a zoom-up function can be executed fast, and the image pick up element can be miniaturized, and sped up with high-precision (e.g. see Patent Literature 1).

Also, as a configuration of the A/D conversion circuit used in Patent Literature 1, a configuration disclosed in Non-Patent Literature 1 is known for example. As illustrated in FIG. 6, an A/D conversion circuit 20 includes a pulse transit circuit 1, an encoder and latch 2, a counter 3, a latch 4, a latch 5, and a computing unit 6. Each function of each element of the configuration will be described.

The pulse travel circuit 1 includes a NAND circuit 101 and a plurality of inverters (INV) 102, which are connected in a ring shape. The NAND circuit 101 is an inverting circuit for booting. If the NAND circuit 101 receives a pulse signal Start P at one input end of the NAND circuit 101, then the NAND circuit 101 starts its operation. The inverter 102 is an inverting circuit.

The encoder and latch 2 encodes and stores an output signal from the pulse transit circuit 1 in synchronization with a sampling signal CKs. The counter 3 measures (counts) the output signal from the pulse transit circuit 1.

The latch 4 stores an output signal from the counter 3 in synchronization with the sampling signal CKs. The latch 5 stores a signal, which is made by adding an output signal from the encoder and latch 2 to an output signal from the latch 4, in synchronization with the sampling signal CKs. The computing unit 6 computes a difference between a previous signal and a present signal by using the latch 5, and outputs to a following circuit outside. Also, a power source line 7A supplies an electric power to the NAND circuit 101 and the inverters 102 in the pulse transit circuit 1. The power source line 7A is connected to an input terminal 8. An analogue input signal Vin on which the A/D conversion is to be performed is input to the input terminal 8.

Next, operation of the A/D conversion circuit 20 will be described. In the pulse transit circuit 1, the pulse signal Start P is transmitted through one NAND circuit 101 and the plurality of inverters 102 that are connected in a ring shape. The number of the loop, in which the pulse signal Start P is transmitted through in the pulse transit circuit 1, and the position of the pulse signal Start P in the NAND circuit 101 and the plurality of inverters 102 are varied based on the magnitude of the analogue input signal Vin and a cycle of the sampling signal CKs. As is illustrated in FIG. 7A, if the analogue input signal Vin becomes larger, then a transmission delay time Ta of the NAND circuit 101 and the plurality of inverters 102 becomes smaller. Therefore, the number of the loop, in which the pulse signal Start P is transmitted through in the pulse transit circuit 1, becomes large.

FIG. 6 will be described again. The encoder and latch 2 detects the position of the pulse signal Start P in the NAND circuit 101 and the plurality of inverters 102, and outputs digital data of a binary number. The counter 3 counts the number of the loop, in which the pulse signal Start P is transmitted through in the pulse transit circuit 1, and outputs digital data of a binary number. The latch 4 latches the digital data from the counter 3. The latch 5 stores digital data that is made by adding the digital data from the latch 4 to the digital data from the encoder and latch 2. Here, the digital data from the latch 4 is disposed in upper bit data of the digital data of the latch 5 and the digital data from the encoder and latch 2 is disposed in lower bit data in the digital data of the latch 5. The computing unit 6 computes a difference between the digital data after stored in the latch 5 and the digital data before stored in the latch 5, and outputs to a following circuit outside.

Then, the A/D conversion circuit 20 outputs a digital data DT (DT1, DT2, DT3, . . . ) periodically corresponding to the analogue input signal Vin based on a sampling period (TS1, TS2, TS3, . . . ) of the sampling signal CKs, as illustrated in FIG. 7B.

In order to acquire an image pickup signal with high-precision in the image pickup element, it is necessary to calculate a difference between a reset level of the pixel and a signal level of the signal that is stored during an exposure period. Therefore, in the A/D conversion unit that is set in the image pickup device, it is necessary to calculate a difference between a count value corresponding to the output signal (reset signal) during the reset period of the pixel cell and a count value corresponding to the output signal (image signal) during the exposure period, and to output as an image pickup signal corresponding to the pixel. This image pickup signal is made by deleting the reset signal from the image signal.

The A/D conversion unit in accordance with the prior art performs an A/D conversion based on the analogue input voltage value Vin in an arbitrary period that is set by the sampling signal. However, in the prior art, the image pickup signal cannot be detected with high-precision from the A/D conversion unit.

### PATENT LITERATURE

Patent Literature 1: Japanese Unexamined Patent Application No. 2006-287879

### Non-Patent Literature

Non-Patent Literature 1: IEEE JOURNAL OF SOLID-STATE CIRCUITS, VOL. 38, NO. 1, JANUARY 2003 An ALL=Digital Analog-to-Digital Converter With 12-uV/LSB Using Moving-Average Filtering

### DISCLOSURE OF INVENTION

### Problems to be Solved by the Invention

The present invention has been realized in view of these conventional technical problems described above. The present invention provides an image pickup device that can detect an image pickup signal with high-precision.

### Means for Solving the Problems

(1) An image pickup device may include a pixel unit that includes a plurality of pixels that are arranged in two-dimensions, an A/D conversion unit that counts and digitizes a clock having a frequency based on a magnitude of an output signal from the pixel to generate a count value, the A/D conversion unit calculating a difference between a first count value and a second count value to output as an image pickup signal of the pixel, the first count value corresponding to the output signal of the pixel during a reset period, the second count value corresponding to the output signal of the pixel during an exposure period, and a control unit that makes the A/D conversion unit perform a counting in the output signal of the pixel during the reset period in each of a plurality of roughly equal successive small periods and sum up the count values in the small periods whose differences in count value from other small periods are within a prescribed fluctuation width among the count values in every small period to generate the first count value, the control unit making the A/D conversion unit perform the counting in the output signal of the pixel during the exposure period in each of the plurality of roughly equal successive small periods and sum up the count value in the small periods whose differences in count value from other small periods are within the prescribed fluctuation width among the count values in every small period to generate the second count value.

(2) If the number of the small periods that are used in calculating the first count value is equal to the number of the small periods that is used in calculating the second count value, then the control unit may not make the A/D conversion unit correct the first count value and the second count value. If the number of the small periods that are used in calculating the first count value is different from the number of the small periods that is used in calculating the second count value, then the control unit may make the A/D conversion unit correct one of the first count value and the second count value based on the number of the small periods.

(3) The control unit may stop an operation of the A/D conversion unit except in a period of performing the counting.

### Effect of the Invention

According to the present invention, the first count value and the second count value are calculated by using a count value in a small period. The difference between the count value in the small period and a count value in the other small period fits in a prescribed fluctuation range. Therefore, it is possible to detect the output signal of the pixel during the reset period and the exposure period with high-precision. Therefore, it is possible to detect the image pickup signal with high-precision.

### BRIEF DESCRIPTION OF THE DRAWINGS

FIG. 1 is a block diagram illustrating a configuration of an image pickup device in accordance with a first preferred embodiment of the present invention.

FIG. 2 is a circuit diagram illustrating a configuration of a pixel in the image pickup device in accordance with the first preferred embodiment of the present invention.

FIG. 3 is a timing chart illustrating an operation of the image pickup device in accordance with the first preferred embodiment of the present invention.

FIG. 4A is a partial enlargement view of the timing chart illustrating the operation of the image pickup device in accordance with the first preferred embodiment of the present invention.

FIG. 4B is a partial enlargement view of the timing chart illustrating the operation of the image pickup device in accordance with the first preferred embodiment of the present invention.

FIG. 5 is a timing chart illustrating an operation of the image pickup device in accordance with the first preferred embodiment of the present invention.

FIG. 6 is a block diagram illustrating a configuration of an A/D conversion unit.

FIG. 7A is a reference view for illustrating an operation of the A/D conversion unit.

FIG. 7B is a reference view for illustrating the operation of the A/D conversion unit.

### BEST MODE FOR CARRYING OUT THE INVENTION

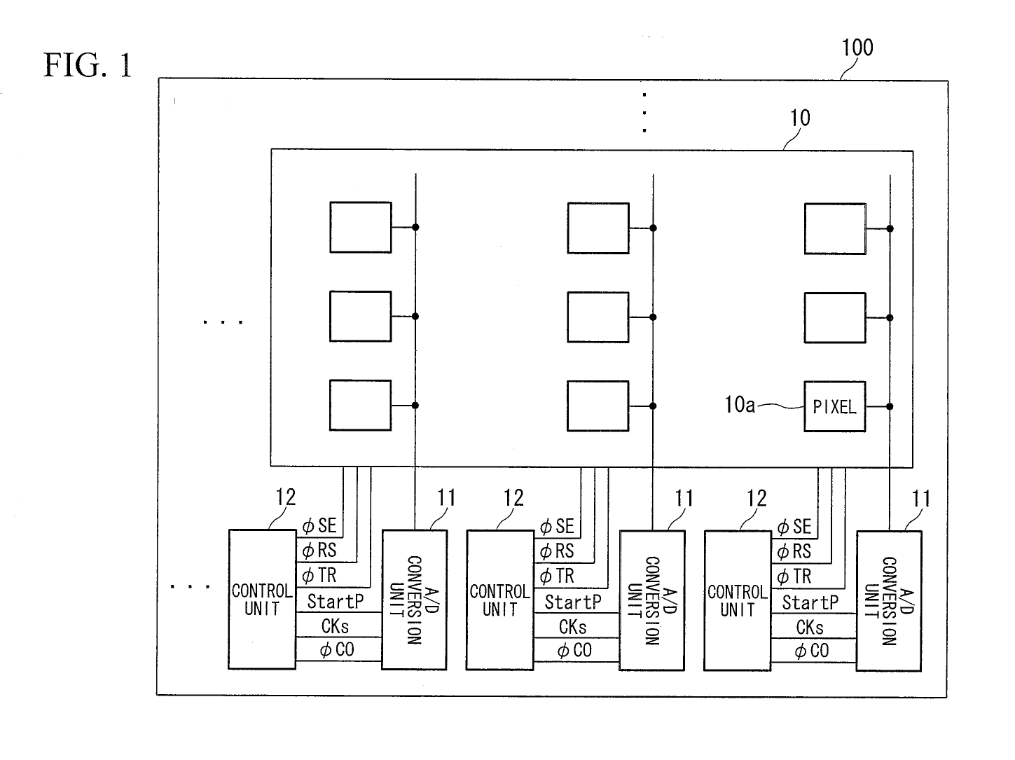

Preferred embodiments of the present invention will be described with reference to the drawings. FIG. 1 is a block diagram illustrating a configuration of an image pickup device 100 in accordance with a first preferred embodiment of the present invention. As illustrated in FIG. 1, the image pickup device 100 includes a pixel unit 10, an A/D conversion unit 11, and a control unit 12. A plurality of pixels 10a are two-dimensionally disposed in the pixel unit 10. Functions of each element will be described.

The pixel unit 10 converts a subject image to an image pickup signal at each pixel 10a. The A/D conversion unit 11 counts a clock having a frequency corresponding to the magnitude of an output signal from the pixel 10a to generate a count value, and operates based on the count value to output as the image pickup signal of the pixel 10a. The control unit 12 supplies various signals including a signal φCO to the A/D conversion unit 11 so as to control the A/D conversion unit 11. The signal φCO controls the counting by the A/D conversion unit 11.

Here, the plurality of pixels 10a that configure the pixel unit 10 may be arranged in one dimension, not in two dimensions.

In the first preferred embodiment, a pair of the A/D conversion unit 11 and the control unit 12 is disposed at each column in the pixel, but only a pair of the A/D conversion unit 11 and the control unit 12 may be disposed at all columns in the pixel.

Further, both the pixel unit 10 and the A/D conversion unit 11 may be disposed in the image pickup element.

Further, the pixel unit 10 may be disposed in the image pickup element, and the A/D conversion unit 11 may be disposed out of the image pickup element.

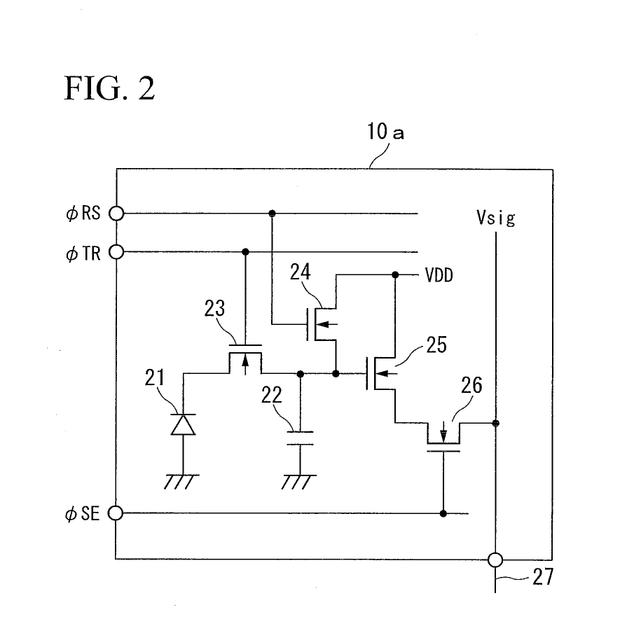

FIG. 2 is a circuit diagram illustrating a configuration of one pixel in the plurality of pixels 10a. As illustrated in FIG. 2, the pixel 10a includes a photoelectric conversion element 21, a memory element 22, a first transistor 23, a second transistor 24, a third transistor 25, and a fourth transistor 26. Functions of each element will be described.

The photoelectric conversion element 21 converts a subject image to a signal charge. The memory element 22 stores the signal charge, which is stored in the photoelectric conversion element 21, and converts it to a voltage. The first transistor 23 transmits the signal charge, which is stored in the photoelectric conversion element 21, to the memory element 22. The second transistor 24 resets the memory element 22. The third transistor 25 amplifies the signal, which is stored in the memory element 22, and outputs it. The fourth transistor 26 controls a selection of the pixel signal by controlling whether to output the signal, which is amplified by the third transistor 25, to a common signal line 27 or not. The first transistor 23 is controlled by a signal φTR from the control unit 12. The second transistor 24 is controlled by a signal φRS from the control unit 12. The fourth transistor 26 is controlled by a signal φSE from the control unit 12.

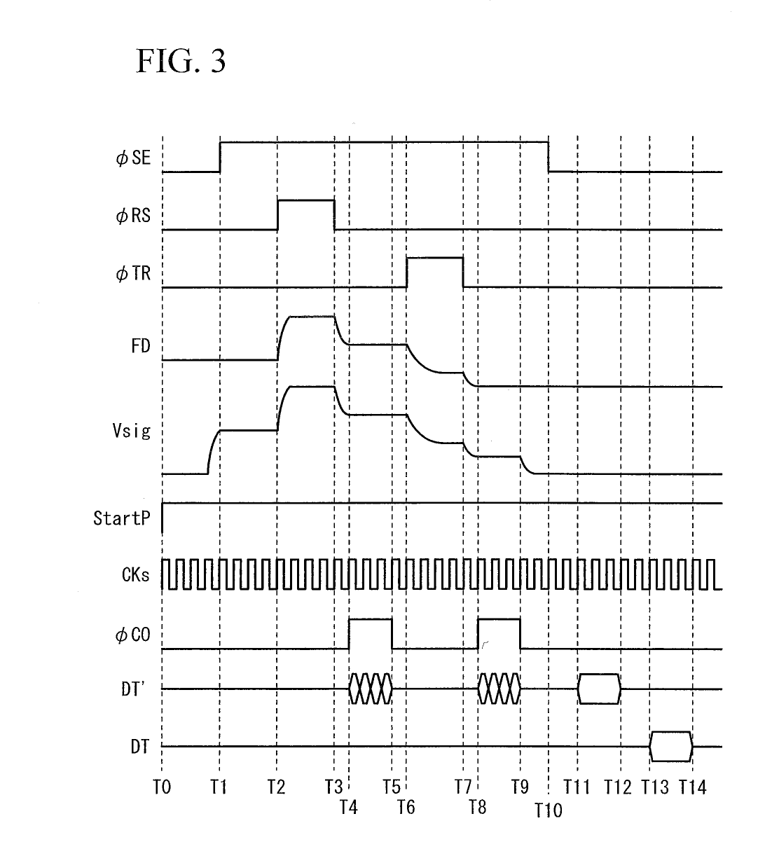

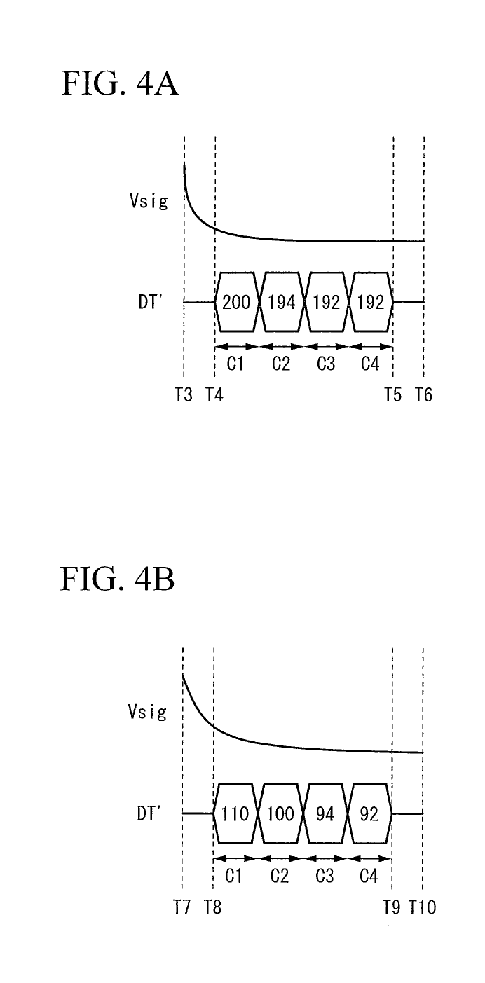

Next, operation of the image pickup device 100 (the configuration of which was described above) will be described using a timing chart. FIG. 3 is a timing chart illustrating an operation of the image pickup device in accordance with the first preferred embodiment of the present invention. FIG. 4A and FIG. 4B are partial enlargement views of FIG. 3.

After the photoelectric conversion element 21 has finished converting the subject image to the image pickup signal, the control unit 12 supplies the pulse signal Start P in “H” level to the A/D conversion unit 11 at time T0. Also, the control unit 12 supplies the sampling signal CKs to the A/D conversion unit 11. The sampling signal CKs has an arbitrary frequency and is output in “H” level and in “L” level alternately. At time T1, the control unit 12 turns the signal φSE to “H” level and turns the fourth transistor 26 to “ON”. Thereby, an arbitrary pixel 10a is connected to the A/D conversion unit 11.

At time T2, the control unit 12 turns the signal φRS to “H” level and turns the second transistor 24 to “ON”. Thereby, the reset operation of the arbitrary pixel 10a is started. At time T3, the control unit turns the signal φRS to “L” level and turns the second transistor 24 to “OFF”. Thereby, the reset operation of the arbitrary pixel 10a is finished.

At time T4, the control unit 12 turns the signal φCO to “H” level. Thereby, the A/D conversion unit 11 starts counting in the reset signal from the pixel 10a in a plurality of nearly equal successive small periods respectively. Also, the A/D conversion unit 11 starts detecting the count values (RWC1, RWC2, . . . ) corresponding to the fluctuation values (W1, W2, . . . ), which fit in the prescribed fluctuation width (RW) set by the control unit 12, and the number of the small periods (TR). The fluctuation width (W1, W2, . . . ) is the difference between the count values (C1, C2, . . . ) corresponding to each small period (difference between the count value of the present small period and the count value of the previous small period). Then, storage by the latch 5 is started. At the time of switching in each small period, the count value is reset.

At time T5, the control unit 12 turns the signal φCO to “L” level. Thereby, the A/D conversion unit 11 stops counting in the reset signal, stops the detections described above, and stops storage by the latch 5.

Concrete example of the value that is stored by the latch 5 at the time T5 will be described. The count values in each small period are C1=200, C2=194, C3=192, and C4=192 (referring to FIG. 4A). Then the fluctuation widths (W1, W2, and W3) of the count values in each small period are as follows.

W1=−6(=C2−C1), W2=−2(=C3−C2), W3=0(=C4−C3).

Also, if the prescribed fluctuation width that is set by the control unit 12 is RW=±5, then the A/D conversion unit 11 selects the fluctuation value (W2 and W3) that is between −5 and +5 from W1, W2 and W3. Then the A/D conversion unit 11 makes the count values C2, C3 and C4, which correspond to the selected fluctuation values W2 and W3, the count values RWC1, RWC2, and RWC3 respectively. As a result, the count values (RWC1, RWC2, and RWC3) of which the fluctuation width in each small period fits in the prescribed fluctuation period are as follows.

RWC1=194, RWC2=192, RWC=192.

Also, the number of small periods (TR) in which the fluctuation width of the count value fits in the prescribed fluctuation width is as follows.

TR=3.

To detect the reset signal precisely, it is necessary to detect the signal in the period in which the output of the pixel is stable in the reset period. The count value that is detected as described above is the signal in the period in which the output of the pixel is stable. Therefore, the reset signal can be detected precisely by calculating the count value of the output of the pixel by using these count values.

At time T6, the control unit 12 turns the signal φTR to “H” level, and turns the first transistor 23 to “ON”. Thereby, the control unit 12 starts transmitting the signal, which is stored in the photoelectric conversion element 21 of the pixel 10a, to the memory element 22. At time T7, the control unit 12 turns the signal φTR to “L” level, and turns the first transistor 23 to “OFF”. Thereby, the control unit 12 stops transmitting the signal, which is stored in the photoelectric conversion element 21 of the pixel 10a, to the memory element 22.

At time T8, the control unit 12 turns the signal φTR to “H” level again. Thereby, the A/D conversion unit 11 starts counting in an image signal from the pixel 10a in a plurality of nearly equal successive small periods respectively. Also, the A/D conversion unit 11 starts detecting of the count values (IWC1, IWC2, . . . ) corresponding to the fluctuation values (W1, W2, . . . ), which fit in the prescribed fluctuation width (IW) set by the control unit 12, and the number of the small periods (TI). The fluctuation width (W1, W2, . . . ) is the difference between the count values (C1, C2, . . . ) corresponding to each small period (difference between the count value and the count value of the previous small period). Then, storing by the latch 5 is started. At the switching time of each small period, the count value is reset.

At time T9, the control unit 12 turns the signal φCO to “L” level again. Thereby, the A/D conversion unit 11 stops counting in the image signal, detections described above and storing by the latch 5.

A concrete example of the value that is stored by the latch 5 at the time T9 will be described hereinafter. The count values of each small period are C1=110, C2=100, C3=94, and C4=92 (referring to FIG. 4B). Then, the fluctuation width (W1, W2, and W3) of the count value of each small period is as follows.

W1=−10(=C2−C1), W2=−6(=C3−C2), W3=−2(=C4−C3).

Also, if the prescribed fluctuation width that is set by the control unit 12 is IW=±5, then the A/D conversion unit 11 selects the fluctuation value (W3) that is between −5 and +5 from W1, W2 and W3. The selected fluctuation value W3 corresponds to the count values C3 and C4. Then the A/D conversion unit 11 sets the count value C3 as the count value IWC1, and sets the count value C4 as the count value IWC2. As a result, the count values (IWC1 and IWC2) of which the fluctuation width in each small period fits in the prescribed fluctuation period are as follows.

IWC1=94, IWC2=92.

Also, the number of the small periods (TI) in which the fluctuation width of the count value fits in the prescribed fluctuation width is as follows.

TI=2.

To detect the image signal precisely, it is necessary to detect the signal of the period in which the output of the pixel is stable in an exposure period. The count value that is detected as described above is the signal of the period in which the output of the pixel is stable. Therefore, the image signal can be detected precisely by calculating the count value of the output of the pixel by using these count values.

At time T10, the control unit 12 turns the signal φSE to “L” level, and turns the fourth transistor 26 to “OFF”. Thereby, the control unit 12 disconnects the connection between an arbitrary pixel 10a and the A/D conversion unit 11.

At time T11, the A/D conversion unit 11 compares the number of the small periods (TR), which is stored by the latch 5 at the time T5, and the number of the small periods (TI), which is stored by the latch 5 at the time T9. The A/D conversion unit 11 determines whether or not to correct an added value (TRC=RWC1+RWC2+ . . . ) of the count values (RWC1, RWC2, . . . ) that is stored by the latch 5 at the time T5 based on the comparison result. Also, the A/D conversion unit 11 determines whether or not to correct an added value (TIC=IWC1+IWC2+ . . . ) of the count values (IWC1, IWC2, . . . ) that is stored by the latch 5 at the time T9 based on the comparison result.

If the numbers of the small periods (TR and TI) are the same, then the A/D conversion unit 11 does not compare the added values TRC and TIC. If the numbers of the small periods (TR and TI) are different, then the A/D conversion unit 11 starts correcting of one of the added values TRC and TIC. If the A/D conversion unit 11 starts correcting of one of the added values TRC and TIC, then the A/D conversion unit 11 stops correcting at time T12.

An example of the correction will be described. If TR>TI, then the A/D conversion unit 11 performs the correction as the following equation (1).

HR=TRC×TI÷TR (1)

Here, examined by using concrete values at the time between T4 and T5 and at the time between T8 and T9, the equation (1) will be as the following equation (2).

HR=(194+192+192)×2÷3=385 (2)

Also, if TI>TR, then the A/D conversion unit 11 performs the correction as the following equation (3).

HI=TIC×TR+TI (3)

The A/D conversion unit 11 counts clock having frequency based on the magnitude of the analogue input voltage value Vin at an arbitrary period. Therefore, the number of the count values becomes larger as the counting period becomes longer. The number of the count values becomes smaller as the counting period becomes shorter. Therefore, the resolution of the image pickup signal generated based on the count value depends on the length of the counting period of the reset signal and the length the counting period of the image signal. Therefore, if the lengths of each count period are different, then the resolution of the image pickup signal, which results from the difference between the count values, is bound by a shorter one of the count periods and the precision of the signal becomes lower. Accordingly, in the preferred embodiment, the count values are corrected so that the counting period of the reset signal and the counting period of the image signal become the same.

At time T13, the A/D conversion unit 11 starts the operation of the image pickup signal in the pixel 10a by using the count value (HR or HI) that is corrected at the time T12, and starts outputting of the signal to an outer following signal processing circuit that is not illustrated in the figure. At time T14, the A/D conversion unit 11 stops the operation of the image pickup signal, and stops outputting of the signal to the outer following signal processing circuit that is not illustrated in the figure.

An example of the operation of the image pickup signal will be described. If TR>TI, then the A/D conversion unit 11 performs the operation of the following equation (4).

DT=HR−TIC (4)

Here, examined by using concrete values at the time between T4 and T5 and at the time between T8 and T9 and the concrete values of (2), the equation (4) will be as the following equation (5).

DT=385−186=199 (5)

Also, if TI>TR, the A/D conversion unit 11 performs the operation as the following equation (6).

DT=TRC−HI (6)

In the operation described above, the time T0 and the time T1, the time T1 and the time T2, the time T3 and the time T4, the time T5 and the time T6, the time T7 and the time T8, the time T9 and the time T10, the time T10 and the time T11, and the time T12 and the time T13 are different times. However, these times may be the same.

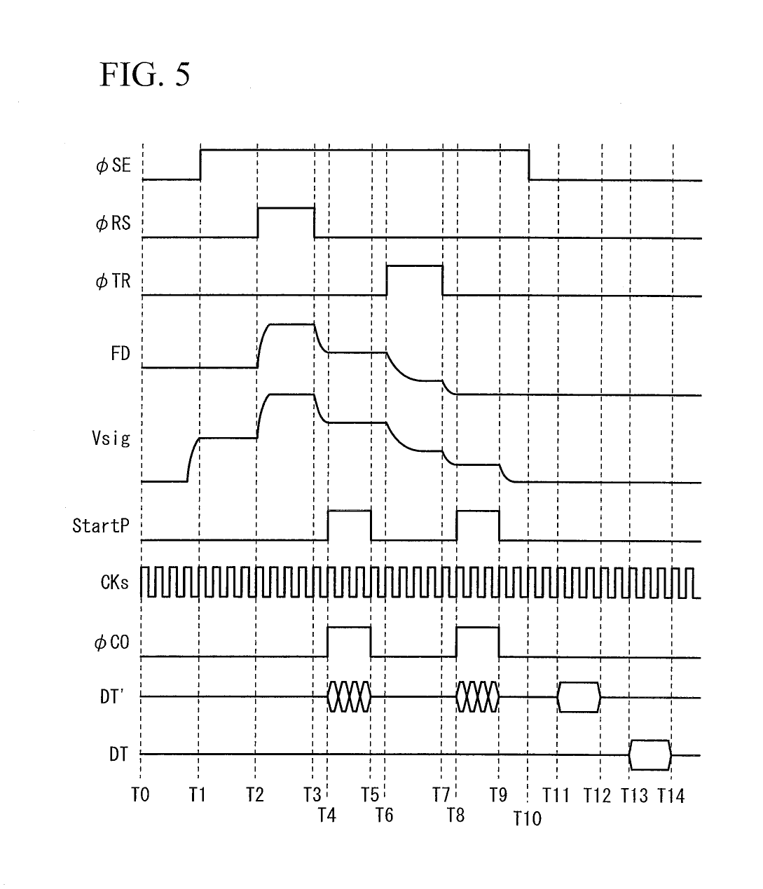

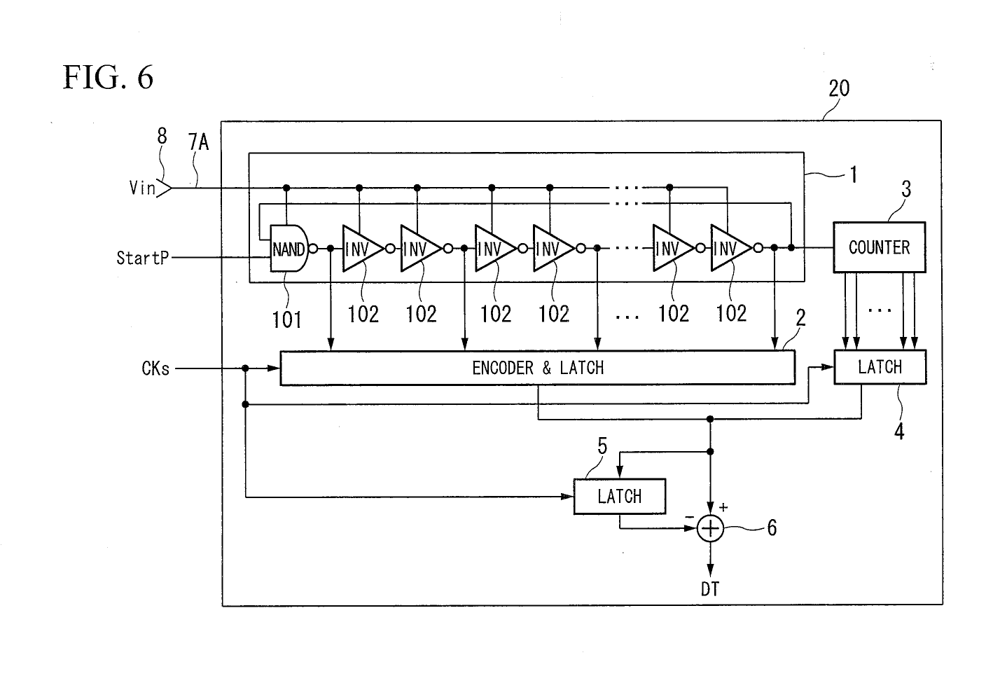

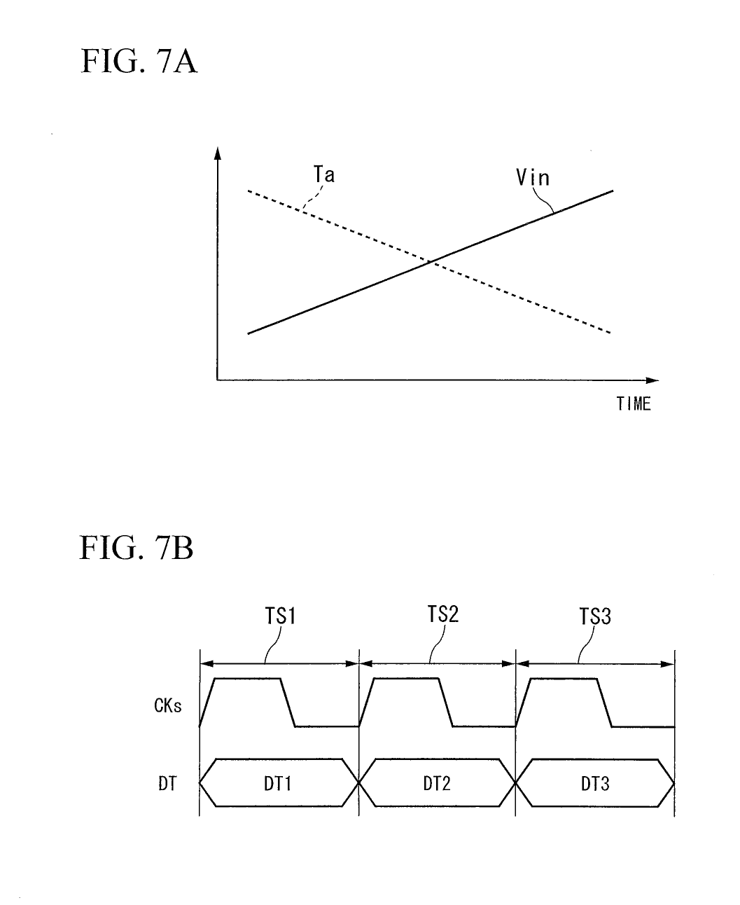

Further, as illustrated in FIG. 5, by turning the pulse signal Start P to “H” level only in the same period as the φC0 signal, the operation of the pulse transit circuit may be stopped at other periods than the period between the time T4 and T5 and the period between the time T8 and T9.

Also, in the preferred embodiment, the correction of the signal and the operation processes, etc. are performed by dividing the reset signal and the image signal from the pixel 10a into four approximately equal successive small periods. However, the number of small periods is not limited to four.

Here, the lengths of each small period are preferably the same, but may be different as long as the difference is within an allowable range. For example, the lengths of each small period may be different as long as the bit numbers of digital vale corresponding to the length of each small period are the same.

As described above, the count value of the reset signal and the count value of the image signal are calculated by using the count value in the small period in which the fluctuation range of the count value in the small period fits in the prescribed fluctuation range. Thereby, the image pickup signal at the pixel 10a can be detected with high-precision, and the image quality at the time of capturing the image can be increased. Also, the operation of the A/D conversion unit 11 at a period other than the reset period and the exposure period can be stopped, and power consumption can be decreased further.

Further, if the number of the small periods (TR) used in calculating the count value (TRC) of the reset signal is different from the number of the small periods (TI) used in calculating the count value (TIC) of the image signal, then the count value (TRC) of the reset signal or the count value (TIC) of the image signal may be corrected based on the number of each small period. Thereby, the reset period and the exposure period can be made the same, and the image pickup signal at the pixel 10a can be detected with high-precision.

While preferred embodiments of the present invention have been described above while referring to the accompanying drawings, it should be understood that these are exemplary and are not to be considered as limited. Various modifications and amendments within the technical field of the patent claims can be made by one of ordinary skill in the art, which is of course understood to belong to the technical field of the present invention.

### INDUSTRIAL APPLICABILITY

The present invention can be applied in an image pickup device that can detect the image pickup signal with high-precision.

### REFERENCE SYMBOLS

10 Pixel unit
10A Pixel
11 A/D conversion unit
12 Control unit
100 Image pickup device

1. An image pickup device comprising:
a pixel unit that includes a plurality of pixels that are arranged in two-dimensions;
an A/D conversion unit that counts and digitizes a clock having a frequency based on a magnitude of an output signal from the pixel to generate a count value, the A/D conversion unit calculating a difference between a first count value and a second count value to output as an image pickup signal of the pixel, the first count value corresponding to the output signal of the pixel during a reset period, the second count value corresponding to the output signal of the pixel during an exposure period; and
a control unit that makes the A/D conversion unit perform a counting in the output signal of the pixel during the reset period in each of a plurality of roughly equal successive small periods and sum up the count values in the small periods whose differences in count value from other small periods are within a prescribed fluctuation width among the count values in every small period to generate the first count value, the control unit making the A/D conversion unit perform the counting in the output signal of the pixel during the exposure period in each of the plurality of roughly equal successive small periods and sum up the count value in the small periods whose differences in count value from other small periods are within the prescribed fluctuation width among the count values in every small period to generate the second count value.

2. The image pickup device according to claim 1, wherein
if the number of the small periods that are used in calculating the first count value is equal to the number of the small periods that is used in calculating the second count value, then the control unit does not make the A/D conversion unit correct the first count value and the second count value, and
if the number of the small periods that are used in calculating the first count value is different from the number of the small periods that is used in calculating the second count value, then the control unit makes the A/D conversion unit correct one of the first count value and the second count value based on the number of the small periods.

3. The image pickup device according to claim 1, wherein the control unit stops an operation of the A/D conversion unit except in a period of performing the counting.
